(19) United States
(12) Patent Application Publication
(10) Pub. No.: US 2025/0096829 A1
(43) Pub. Date: Mar. 20, 2025

(54) Digital Pre-Distortion Circuit, Digital Pre-Distortion Method, and Apparatus

(71) Applicant: Huawei Technologies Co., Ltd., Shenzhen (CN)

(72) Inventors: Andrey Vorobyev, Moscow (RU); Nefedov Maxim, Moscow (RU); Yifan Zhao, Shanghai (CN); Yanming Wu, Shanghai (CN); Liuchuang Gao, Shanghai (CN)

(21) Appl. No.: 18/962,766

(22) Filed: Nov. 27, 2024

Related U.S. Application Data
(63) Continuation of application No. PCT/CN2023/070659, filed on Jan. 5, 2023.

(30) Foreign Application Priority Data
May 27, 2022 (RU) RU2022114387

(51) Int. Cl. H04B 1/04; H03F 1/32; H03F 3/24

(52) U.S. Cl. CPC H04B 1/0475; H03F 1/3241; H03F 3/245; H03F 2200/451

(57) ABSTRACT

A digital pre-distortion (DPD) circuit includes a DPD and a power amplifier (PA). The DPD module is configured to: obtain features of a first input signal, determine a first coefficient and a second coefficient based on the features of the first input signal, generate a second signal based on the first input signal and the first coefficient, generate a first output signal based on the second signal and the second coefficient, and input the first output signal to the power amplifier. The PA is configured to amplify the first output signal to generate a second output signal.

### CROSS-REFERENCE TO RELATED APPLICATIONS

This is a continuation of International Patent Application No. PCT/CN2023/070659 filed on Jan. 5, 2023, which claims priority to Russian Patent Application No. 2022114387 filed on May 27, 2022. The disclosures of the aforementioned applications are hereby incorporated by reference in their entireties.

### TECHNICAL FIELD

Embodiments of this disclosure relate to the field of electronic devices, and more specifically, to a digital pre-distortion (DPD) circuit, a DPD method, and an apparatus.

### BACKGROUND

In a communication system, DPD is introduced to avoid non-linearity and memory distortion of a signal caused because a power amplifier (PA) operates in a non-linear area. As PAs develop toward high efficiency, a large bandwidth, low power consumption, and high integration, a current DPD system can no longer meet a requirement of the PAs.

### SUMMARY

Embodiments of this disclosure provide a DPD circuit, a DPD method, and an apparatus, so that a DPD coefficient and an index coefficient can be determined based on a first feature and a second feature of an input signal, to perform DPD and avoid a non-linear output signal obtained through a PA.

According to a first aspect, a DPD circuit is provided. The DPD circuit includes a DPD module and a PA. The DPD module is configured to obtain a first feature of a first input signal and a second feature of the first input signal, where the first feature of the first input signal includes at least one of the following: an amplitude of the first input signal, an in-phase component of the first input signal, and a quadrature component of the first input signal, and the second feature includes at least one of the following: a bandwidth of the first input signal, a temperature at which the DPD circuit processes the first input signal, a frequency of the first input signal, a modulation format of the first input signal, and a standing wave generated when the DPD circuit processes the first input signal. The DPD module is configured to: determine a first coefficient based on the first feature, and determine a second coefficient based on the second feature, and is configured to: generate a second signal based on the first input signal and the first coefficient, generate a first output signal based on the second signal and the second coefficient, and input the first output signal to the PA.

The PA is configured to amplify the first output signal, to generate a second output signal.

According to the DPD circuit provided in this embodiment of this disclosure, the DPD module may determine the first coefficient and the second coefficient based on the first feature and the second feature of the first input signal, perform DPD on the first input signal by using the first coefficient and the second coefficient, and then input a first output signal obtained through DPD to the PA, to obtain the second output signal that is linear and undistorted.

With reference to the first aspect, in some implementations of the first aspect, the DPD circuit further includes a coefficient module. The coefficient module stores a correspondence between the first feature and the first coefficient and a correspondence between the second feature and the second coefficient. The DPD module is configured to: extract the first coefficient from the coefficient module based on the first feature, and extract the second coefficient from the coefficient module based on the second feature.

With reference to the first aspect, in some implementations of the first aspect, the DPD module includes N DPD submodules and a synthesis module. The N DPD submodules are configured to: determine N first sub-coefficients based on the first feature, and determine N second sub-coefficients based on the second feature, where N≥1 and Nis an integer, and the N first sub-coefficients are different; generate N second sub-signals based on the first input signal and the N first sub-coefficients; and generate N first output sub-signals based on the N second sub-signals and the N second sub-coefficients. The synthesis module is configured to generate the first output signal based on the N first output sub-signals.

With reference to the first aspect, in some implementations of the first aspect, the first feature further includes data carried in the first input signal and/or a signal amplitude of a second input signal and/or data carried in the second input signal. The second input signal may be an input signal that has a specific time interval from the first input signal.

With reference to the first aspect, in some implementations of the first aspect, the DPD circuit further includes a digital-to-analog converter. The digital-to-analog converter is configured to: obtain the first output signal from the DPD circuit, perform digital-to-analog conversion on the first output signal, and input a first output signal obtained through the digital-to-analog conversion to the PA.

With reference to the first aspect, in some implementations of the first aspect, the DPD circuit further includes a preprocessing module and a solution module. An algorithm used to solve for a coefficient is preset in the solution module, and the first input signal and the second output signal are input to the preprocessing module. When an adjacent channel leakage ratio (ACLR) of the first input signal to the second output signal exceeds a first threshold and/or an error vector magnitude (EVM) exceeds a second threshold, the preprocessing module is configured to: preprocess the first input signal and the second output signal, to align the first input signal with the second output signal, and input a preprocessed first input signal and a preprocessed second output signal to the solution module; the solution module is configured to process the preprocessed first input signal and the preprocessed second output signal according to the algorithm, to generate a third coefficient and a fourth coefficient; the DPD module is further configured to: generate a third signal based on the first input signal and the third coefficient, generate a third output signal based on the third signal and the fourth coefficient, and input the third output signal to the PA; and the PA is configured to amplify the third output signal.

In this embodiment of this disclosure, when the ACLR of the first input signal to the second output signal exceeds the first threshold or the EVM exceeds the second threshold, the DPD circuit may re-solve for a new coefficient based on the first input signal and the second output signal, so that the DPD circuit can generate the third output signal based on the third coefficient and the fourth coefficient, and then input the third output signal to the PA, to further obtain the undistorted fourth output signal.

According to a second aspect, a DPD method is provided. The method includes: obtaining a first feature of a first input signal and a second feature of the first input signal, where the first feature of the first input signal includes at least one of the following: an amplitude of the first input signal, an in-phase component of the first input signal, and a quadrature component of the first input signal, and the second feature includes at least one of the following: a bandwidth of the first input signal, a temperature at which a DPD circuit processes the first input signal, a frequency of the first input signal, a modulation format of the first input signal, and a standing wave generated when the DPD circuit processes the first input signal; determining a first coefficient based on the first feature, and determining a second coefficient based on the second feature; generating a second signal based on the first input signal and the first coefficient; generating a first output signal based on the second signal and the second coefficient; and performing power amplification on the first output signal, to generate a second output signal.

With reference to the second aspect, in some implementations of the second aspect, the determining a first coefficient and a second coefficient based on the first feature and the second feature of the first input signal includes: determining N first sub-coefficients based on the first feature, and determining N second sub-coefficients based on the second feature, where the N first sub-coefficients are different; the generating a second signal based on the first input signal and the first coefficient includes: generating N second sub-signals based on the first input signal and the N first sub-coefficients; and the generating a first output signal based on the second signal and the second coefficient includes: generating N first output sub-signals based on the N second sub-signals and the N second sub-coefficients; and generating the first output signal based on the N first output sub-signals.

With reference to the second aspect, in some implementations of the second aspect, when an ACLR of the first input signal to the second output signal exceeds a first threshold and/or an EVM exceeds a second threshold, the method further includes: preprocessing the first input signal and the second output signal, to align the first input signal with the second output signal; processing a preprocessed first input signal and a preprocessed second output signal, to generate a third coefficient and a fourth coefficient; generating a third signal based on the first input signal and the third coefficient; generating a third output signal based on the third signal and the fourth coefficient; and performing power amplification on the third output signal, to generate a fourth output signal.

With reference to the second aspect, in some implementations of the second aspect, the first feature further includes data carried in the first input signal and/or a signal amplitude of a second input signal and/or data carried in the second input signal. The second input signal may be an input signal that has a specific time interval from the first input signal.

According to a third aspect, a transmitting apparatus is provided. The transmitting apparatus includes a transceiver unit, a DPD unit, and a power amplification unit. The transceiver unit is configured to receive a first input signal. The DPD unit is configured to: obtain a first feature of the first input signal and a second feature of the first input signal, where the first feature of the first input signal includes at least one of the following: an amplitude of the first input signal, an in-phase component of the first input signal, and a quadrature component of the first input signal, and the second feature includes at least one of the following: a bandwidth of the first input signal, a temperature at which the DPD circuit processes the first input signal, a frequency of the first input signal, a modulation format of the first input signal, and a standing wave generated when the DPD circuit processes the first input signal; determine a first coefficient based on the first feature, and determine a second coefficient based on the second feature; generate a second signal based on the first input signal and the first coefficient; generate a first output signal based on the second signal and the second coefficient; and input the first output signal to the power amplification unit. The power amplification unit is configured to amplify the first output signal, to generate a second output signal. The transceiver unit is further configured to send the second output signal.

With reference to the third aspect, in some implementations of the third aspect, the transmitting apparatus further includes a coefficient unit. The coefficient unit stores a correspondence between the first feature and the first coefficient and a correspondence between the second feature and the second coefficient. The DPD unit is configured to: extract the first coefficient from the coefficient unit based on the first feature, and extract the second coefficient from the coefficient unit based on the second feature.

With reference to the third aspect, in some implementations of the third aspect, the digital preprocessing unit is configured to: determine N first sub-coefficients based on the first feature, and determine N second sub-coefficients based on the second feature, where the N first sub-coefficients are different; generate N second sub-signals based on the first input signal and the N first coefficients; generate N first output sub-signals based on the N second sub-signals and the N second sub-coefficients; and generate the first output signal based on the N first output sub-signals.

With reference to the third aspect, in some implementations of the third aspect, the transmitting apparatus further includes a preprocessing unit and a solution unit. An algorithm used to solve for a coefficient is preset in the solution unit, and the first input signal and the second output signal are input to the preprocessing unit. When an ACLR of the first input signal to the second output signal exceeds a first threshold or an EVM exceeds a second threshold, the preprocessing unit is configured to preprocess the first input signal and the second output signal, to align the first input signal with the second output signal; the preprocessing unit is further configured to input a preprocessed first input signal and a preprocessed second output signal to the solution unit; the solution unit is configured to process the preprocessed first input signal and the preprocessed second output signal according to the algorithm, to generate a third coefficient and a fourth coefficient; the DPD unit is further configured to generate a third signal based on the first input signal and the third coefficient; generate a third output signal based on the third signal and the fourth coefficient; and input the third output signal to the power amplification unit; the power amplification unit is further configured to amplify the third output signal; and the transceiver unit is further configured to send an amplified third output signal.

With reference to the third aspect, in some implementations of the third aspect, the first feature further includes data carried in the first input signal and/or a signal amplitude of a second input signal and/or data carried in the second input signal. The second input signal may be an input signal that has a specific time interval from the first input signal.

According to a fourth aspect, a transmitting device is provided. The transmitting device includes the DPD circuit according to the first aspect and any one of the possible implementations of the first aspect, or includes the transmitting apparatus according to the third aspect and any one of the possible implementations of the third aspect.

According to a fifth aspect, a transmitting device is provided, including one or more processors, one or more memories, and one or more transceivers. The one or more memories store one or more computer programs, the one or more computer programs include instructions, and when the instructions are executed by the one or more processors, the technical solution according to the second aspect and any one of the possible designs of the second aspect is performed.

According to a sixth aspect, a chip is provided. The chip is coupled to a memory in an electronic device, and is configured to: invoke a computer program stored in the memory, and perform the technical solution according to the second aspect and any one of the possible designs of the second aspect in embodiments of this disclosure. In embodiments of this disclosure, “coupling” means that two components are directly or indirectly combined with each other.

According to a seventh aspect, a computer-readable storage medium is provided. The computer-readable storage medium includes a computer program. When the computer program is run on a communication apparatus, an electronic device is enabled to perform the technical solution according to the second aspect and any one of the possible designs of the second aspect.

According to an eighth aspect, a computer program product is provided. The computer program product includes a computer program. When the computer program is run, a computer is enabled to perform the technical solution according to the second aspect and any one of the possible designs of the second aspect.

For beneficial effects of the second aspect to the eighth aspect, refer to the beneficial effects of the first aspect. Details are not described again.

### BRIEF DESCRIPTION OF DRAWINGS

FIG. 1 is a schematic flowchart of a linearization solution for DPD.

FIG. 2 is a diagram of a structure of a DPD circuit according to an embodiment of this disclosure.

FIG. 3 is a diagram of determining a first coefficient by a DPD module according to an embodiment of this disclosure.

FIG. 4 is another diagram of determining a first coefficient by a DPD module according to an embodiment of this disclosure.

FIG. 5 is a diagram of a structure of a DPD module according to an embodiment of this disclosure.

FIG. 6 is a diagram of a structure of a DPD submodule according to an embodiment of this disclosure.

FIG. 7 is a diagram of a structure of a coefficient module according to an embodiment of this disclosure.

FIG. 8 is a diagram of a structure of a DPD circuit according to an embodiment of this disclosure.

FIG. 9 is a diagram of a structure of a DPD circuit according to an embodiment of this disclosure.

FIG. 10 is a diagram of a structure of a DPD circuit according to an embodiment of this disclosure.

FIG. 11 is a schematic flowchart of a DPD method according to an embodiment of this disclosure.

FIG. 12 is a schematic flowchart of an example of a DPD method according to an embodiment of this disclosure.

FIG. 13 is a schematic flowchart of an example of a DPD method according to an embodiment of this disclosure.

FIG. 14 shows a transmitting apparatus according to an embodiment of this disclosure.

FIG. 15 shows a communication apparatus according to an embodiment of this disclosure.

### DESCRIPTION OF EMBODIMENTS

The following describes technical solutions of this disclosure with reference to accompanying drawings.

The technical solutions of embodiments of this disclosure may be applied to various communication systems, such as a Global System for Mobile Communications (GSM), a code-division multiple access (CDMA) system, a wideband code-division multiple access (WCDMA) system, a General Packet Radio Service (GPRS), a Long-Term Evolution (LTE) system, an LTE frequency-division duplex (FDD) system, an LTE time-division duplex (TDD) system, a Universal Mobile Telecommunications System (UMTS), a Worldwide Interoperability for Microwave Access (WiMAX) communication system, a 5th generation (5G) system or a New Radio (NR) system, and a future evolved communication system. Further, the technical solutions provided in embodiments of this disclosure may be applied to another communication system that needs to implement DPD. In the communication system, a device using the technical solutions provided in embodiments of this disclosure is a transmitting device, and the transmitting device may be a network device, or may be a terminal device. The transmitting device may also be referred to as a sending device.

The terminal device is a device having a wireless transceiver function, and may be deployed on land, including an indoor device, an outdoor device, a handheld device, a wearable device, or a vehicle-mounted device, may be deployed on a water surface (for example, on a ship), or may be deployed in air (for example, on a plane, a balloon, or a satellite). The terminal device may communicate with a core network through a radio access network (RAN), and exchange a voice and/or data with the RAN. The terminal device may be a mobile phone, a tablet computer (Pad), a computer having a wireless transceiver function, a mobile internet device (MID), a wearable device, a virtual reality (VR) terminal device, an augmented reality (AR) terminal device, a wireless terminal in industrial control, a wireless terminal in self driving, a wireless terminal in telemedicine (remote medical), a wireless terminal in a smart grid, a wireless terminal in transportation safety, a wireless terminal in a smart home, an uncrewed aerial vehicle, and an uncrewed aerial vehicle controller. Application scenarios are not limited in embodiments of this disclosure. The terminal device sometimes may also be referred to as user equipment (UE), a mobile station, a remote station, and the like. A specific technology, a device form, and a name that are used by the terminal device are not limited in embodiments of this disclosure.

The network device in embodiments of this disclosure includes a base station (BS), a network controller, a mobile switching center, another access network device, or a core network device. The BS includes a macro BS, a micro BS, a relay station, an access point, or the like in various forms. For example, the BS may be a BS in the GSM or the CDMA, that is, a base transceiver station (BTS), may be a BS in the WCDMA, that is, a NodeB, may be an evolved BS in the LTE, that is, an eNB or an e-NodeB, or may be a BS in the 5G system. The BS in the 5G system may be referred to as a transmission reception point (TRP), or may be referred to as a next generation nodeB (generation NodeB, gNB). Further, the BS may be a BS in a future network. This is not limited in this disclosure.

The technical solutions provided in embodiments of this disclosure may be applied to the transmitting device, and further, may be applied to a transmitting apparatus of the transmitting device.

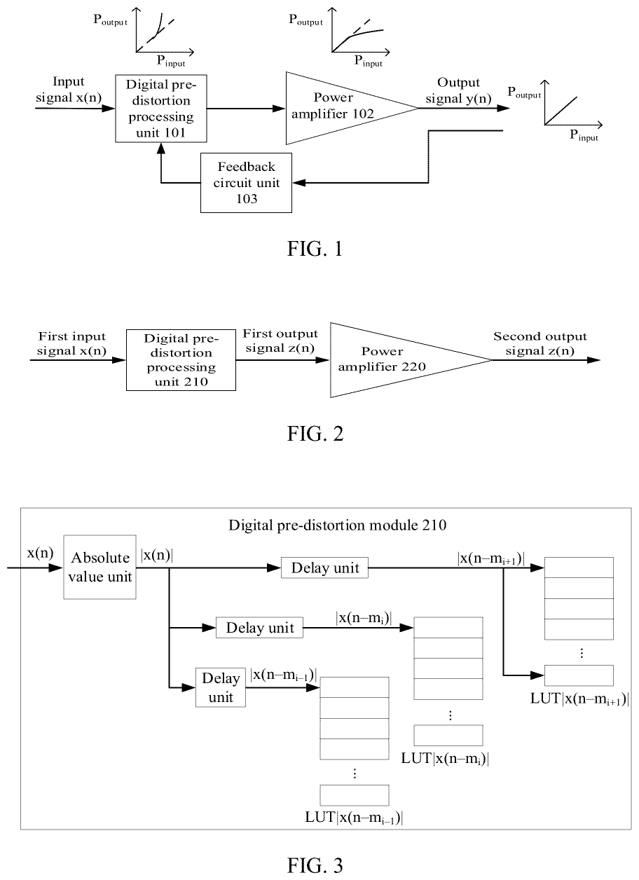

A PA is a non-linear component. To avoid distortion in a signal amplification process, linearization needs to be performed on the PA. Currently, a DPD solution may be used for the linearization of the PA. FIG. 1 is a schematic flowchart of a linearization solution for DPD. As shown in FIG. 1, it is assumed that an input signal x(n) is directly input to a PA 102 without being processed by a DPD processing unit 101. When the input signal x(n) passes through the PA 102, due to a non-linear feature of the PA 102, signal distortion may be caused, and a non-linear distorted signal may be output. This may affect signal quality and communication efficiency. The DPD processing unit 101 is configured to perform preprocessing that is opposite to the feature of the PA 102 on the input signal x(n) before the input signal x(n) is input to the PA 102. In FIG. 2, in a coordinate graph above the DPD processing unit 101, a Pᵢₙₚᵤₜ on a horizontal axis represents a signal input to the DPD processing unit 101, a Pₒᵤₜₚᵤₜ on a vertical axis represents a signal output by the DPD processing unit 101, and a dashed line represents an undistorted input signal x(n) input to the DPD processing unit 101. Due to the non-linear feature of the PA, processing that is opposite to the non-linear feature of the PA 102 needs to be performed in the DPD processing unit 101. In this case, a solid line represents a feature of a signal actually output from the DPD processing unit 101. In a coordinate graph above the PA 102, a dashed line represents an undistorted input signal input to the PA 102. Due to the non-linear feature of the PA 102, a solid line represents a signal that is obtained, due to the non-linear feature of the PA 102, through output of the undistorted input signal input to the PA 102. It can be learned that, due to the non-linear feature of the PA 102, the signal output from the PA 102 may be distorted. Therefore, processing that is opposite to the non-linear feature of the PA 102 needs to be performed in the DPD processing unit 101. A feedback circuit unit 103 is disposed. To be specific, a part of the signal output from the PA passes through the feedback circuit unit 103 and then is transmitted to the DPD processing unit 101. The DPD processing unit 101 may obtain the non-linear feature of the PA 102 by processing the part of the signal, and therefore, processing that is opposite to the non-linear feature of the PA 102 may be performed in the DPD processing unit 101 in advance, and then a signal processed by the DPD processing unit 101 is input to the PA 102. Finally, the PA 102 may output a linear and undistorted signal. This ensures that the signal output from the PA 102 is linear and undistorted. In a coordinate graph on a right side of the PA 102, a solid line represents the signal output by the PA 102. It can be learned that, after pre-distortion is performed by the DPD processing unit 101, the signal output by the PA 102 is not distorted.

A non-linear distortion feature of the PA may be expressed by a polynomial. Therefore, the PA may be modeled by using the polynomial. Common PA models include a Volterra model, a memory polynomial (MP) model, a generalized memory polynomial (GMP) model, a Wiener model, a Hammerstein model, and the like. A mathematical expression of the memory polynomial model is shown in Formula (1):

$$z ( n ) = {\sum }_{k = 1}^{K} {\sum }_{q = 0}^{Q - 1} ax ( n - q ) {\vert x ( n - q ) \vert}^{k - 1} \qquad ( 1 )$$

x(n) indicates the input signal, z (n) indicates an output signal of the DPD processing unit, K indicates a polynomial order, Q indicates a memory depth, and a indicates a DPD coefficient.

To perform pre-distortion according to Formula (1), the DPD coefficient a needs to be calculated. There is a plurality of methods for calculating the DPD coefficient a. This is not limited in embodiments of this disclosure.

Currently, when calculating the DPD coefficient, the feedback circuit unit needs to perform real-time iteration, which may increase additional power consumption. In addition, as a second feature (for example, a bandwidth, a temperature, or a frequency) changes, it is difficult for the feedback circuit unit to quickly obtain the DPD coefficient through calculation. Consequently, communication quality deteriorates. Based on this, embodiments of this disclosure provide a DPD circuit and an apparatus, to reduce power consumption and improve communication quality.

FIG. 2 is a diagram of a structure of a DPD circuit according to an embodiment of this disclosure. As shown in FIG. 2, the DPD circuit 200 includes a DPD module 210 and a PA 220.

The DPD module 210 is configured to obtain a first feature of a first input signal and a second feature of the first input signal.

The DPD module 210 is configured to determine a first coefficient based on the first feature of the first input signal, and determine a second coefficient of the second feature based on the second feature.

The DPD module 210 is further configured to generate a second signal based on the first input signal and the first coefficient.

The DPD module 210 is further configured to generate a first output signal based on the second signal and the second coefficient.

The DPD module 210 is further configured to input the first output signal to the PA.

The PA 220 is configured to amplify the first output signal.

In this embodiment of this disclosure, a first output signal obtained through power amplification may be referred to as a second output signal.

According to the DPD circuit provided in this embodiment of this disclosure, the DPD module may determine the first coefficient and the second coefficient based on the first feature and the second feature of the first input signal, perform DPD on the first input signal by using the first coefficient and the second coefficient, and then input a first output signal obtained through DPD to the PA 220, to obtain the second output signal that is linear and undistorted.

The following describes in detail the DPD circuit provided in this embodiment of this disclosure.

After the first input signal is input to the DPD module 210, the DPD module 210 may obtain the first feature and the second feature of the first input signal, and then determine the first coefficient based on the first feature and determine the second coefficient based on the second feature.

A type of the first input signal is not limited in embodiments of this disclosure. The first input signal may be a modulation signal, for example, an LTE signal or a 5G signal, or may be a continuous wave (CW) signal.

Optionally, the first feature of the first input signal may be a signal amplitude.

Optionally, the first feature of the first input signal may further include data carried in the first input signal and/or a signal amplitude of a second input signal and/or data carried in the second input signal. The data carried in the first input signal may be an in-phase component and a quadrature component of the first input signal, and the second input signal may be an input signal that has a specific time interval from the first input signal. For example, the first input signal is x(n), and the second input signal may be x(n−k). In this case, the feature of the first input signal may alternatively be the amplitude of the second input signal, that is, |x(n−k)|.

The DPD module 210 may determine the first coefficient in the following several manners.

In a possible implementation, the DPD module 210 stores a look-up table (LUT). The look-up table may be understood as a mapping relationship. The mapping relationship indicates a correspondence between a plurality of first-type features and a plurality of coefficients. To be specific, the pre-calculated coefficients are stored in the table, and then, the DPD module 210 may calculate an address in the LUT based on the first feature of the first input signal, to determine the first coefficient. The first coefficient may be understood as a coefficient corresponding to the first feature in the mapping relationship. The first-type feature includes at least one of the amplitude, the in-phase component, and the quadrature component.

For example, the first feature is the amplitude of the first input signal. As shown in FIG. 3, the DPD module 210 may determine, through an absolute value unit, that an absolute value of the first input signal x(n) input to the DPD module 210 is |x(n)|. The absolute value |x(n)| of the first input signal indicates the signal amplitude of the first input signal. After determining the absolute value |x(n)| of the first input signal, the DPD module 210 may obtain at least one index value through adjustment by a delay unit. As shown in FIG. 3, the DPD module 210 may obtain an index value |x(n−m₁)| whose memory depth is m₁, an index value |x(n−m₂)| whose memory depth is m₂, and an index value |x(n−m₃)| whose memory depth is m₃, then determine LUTs corresponding to the index values based on the index values, that is, may determine 3 LUTs, and then search for corresponding coefficients in the corresponding LUTs based on the signal amplitude of the first input signal. In embodiments of this disclosure, the coefficient determined by using the LUT is referred to as a DPD coefficient. In other words, DPD coefficients of different memory terms in a memory polynomial may be determined based on the signal amplitude of the first input signal.

It should be noted that the memory depth is related to the memory polynomial. In this embodiment of this disclosure, an example in which the DPD module 210 obtains the index values of the three memory depths through the delay unit is used. However, embodiments of this disclosure are not limited thereto.

In a possible implementation, the DPD circuit 200 further includes a coefficient module 230. The coefficient module 230 stores a LUT. The look-up table may be understood as a mapping relationship. The mapping relationship indicates a correspondence between a plurality of first-type features and a plurality of coefficients. To be specific, the pre-calculated coefficients are stored in the table, and then, the DPD module 210 may calculate an address in the LUT based on the first feature of the first input signal, to determine the first coefficient.

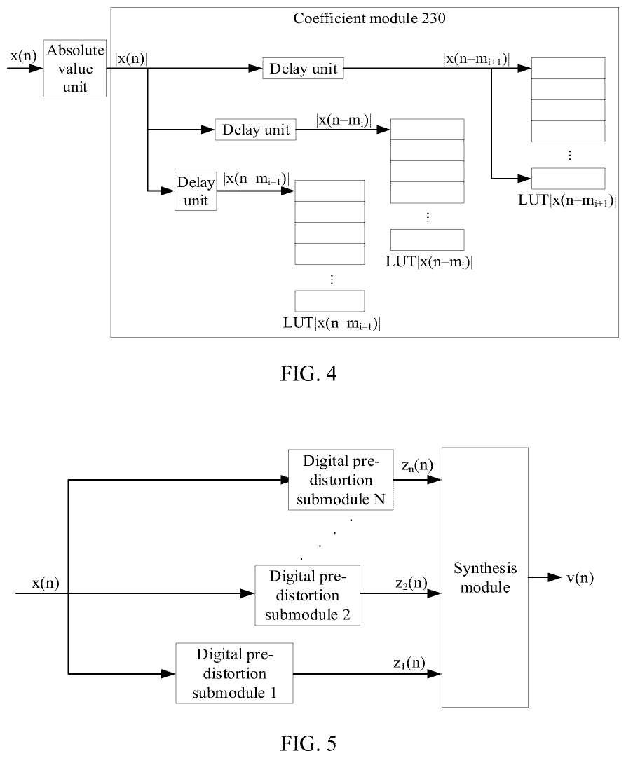

For example, as shown in FIG. 4, an absolute value |x(n)| of the first input signal may be obtained after the first input signal passes through an absolute value unit. The absolute value of the first input signal is input to the coefficient module 230, and the coefficient module 230 may obtain an index value |x(n−m₁)| whose memory depth is m₁, an index value |x(n−m₂)| whose memory depth is m₂, and an index value |x(n−m₃)| whose memory depth is m₃ through adjustment by the delay unit, then determine LUTs corresponding to the index values based on the index values, that is, may determine 3 LUTs, and then search for corresponding coefficients in the corresponding LUTs based on the signal amplitude of the first input signal. When the corresponding coefficients are searched for in the corresponding LUTs based on the signal amplitude of the first input signal, DPD coefficients of different memory terms may be determined. For specific descriptions, refer to the following descriptions.

Optionally, the second feature of the first input signal includes at least one of the following: a bandwidth of the first input signal, a temperature at which the DPD circuit processes the first input signal, a frequency of the first input signal, a modulation format of the first input signal, and a standing wave generated when the DPD circuit processes the first input signal.

In this embodiment of this disclosure, the DPD module may determine the second coefficient in the following several manners.

In a possible implementation, the DPD module 210 stores an index table. The index table may be understood as a mapping relationship. The mapping relationship indicates a correspondence between a plurality of second-type features and a plurality of coefficients. The DPD module 210 may find the corresponding second coefficient in the index table based on the second feature of the first input signal. The second coefficient may be understood as a coefficient corresponding to the second feature in the mapping relationship. The second-type feature includes at least one of the bandwidth, the temperature, the frequency, the signal modulation format, and the standing wave.

In a possible implementation, the DPD circuit 200 further includes the coefficient module 230, and the coefficient module 230 stores an index table. The DPD module 210 may determine the second coefficient in the coefficient module 230 based on the second feature of the first input signal.

It may be understood that, when the first input signal includes a plurality of second features, there are also a plurality of index tables stored in the DPD module 210 or the coefficient module 230.

For example, when the first input signal includes M second features, the DPD module may determine M second sub-coefficients based on the M second features of the first input signal. In other words, the second coefficient may include the M second sub-coefficients. For example, when the second feature is the bandwidth and the temperature, the DPD module 210 or the coefficient module 230 may store a first index table and a second index table. The first index table corresponds to the bandwidth, and the second index table corresponds to the temperature. Therefore, corresponding coefficients may be respectively determined in the first index table and the second index table based on the bandwidth and the temperature. In this embodiment of this disclosure, a coefficient set determined based on different second features of the first input signal may be referred to as the second coefficient. In other words, the second coefficient may include a plurality of coefficients determined based on the different second features of the first input signal. In the foregoing example, the second coefficient includes the coefficient determined based on the bandwidth and the coefficient determined based on the temperature.

It is described above that the DPD module 210 determines the first coefficient and the second coefficient based on the first feature and the second feature of the first input signal. The following describes in detail that the DPD module 210 generates the second signal based on the first coefficient and the first input signal, and generates the first output signal based on the second signal and the second coefficient.

After the DPD module 210 determines the first coefficient based on the first feature of the first input signal, the first coefficient may include one DPD coefficient or a plurality of DPD coefficients of different memory terms, and the DPD module 210 may multiply the first input signal by the first coefficient, that is, multiply the first input signal by the DPD coefficient or the plurality of DPD coefficients of different memory terms, to obtain the second signal. After the second signal is generated, the second signal may be multiplied by the second coefficient to obtain the first output signal.

Optionally, in some embodiments, the DPD module 210 may include N DPD submodules and a synthesis module. N≥1 and N is an integer.

FIG. 5 is a diagram of a structure of the DPD module 210. As shown in FIG. 5, the DPD module 210 includes the N DPD submodules and the synthesis module. The N DPD submodules may determine N first sub-coefficients based on a first feature of the first input signal x(n) and determine N second sub-coefficients based on a second feature of the first input signal. N≥1 and Nis an integer. Each of the N first sub-coefficients may include one DPD coefficient or a plurality of DPD coefficients. That the first sub-coefficient includes the plurality of DPD coefficients may be understood as that the first sub-coefficient includes the DPD coefficients of different memory terms. It may be understood that the N first sub-coefficients may form the first coefficient. In other words, the first coefficient may include the N first sub-coefficients. Similarly, the second coefficient includes the N second sub-coefficients. The N DPD submodules may generate N second sub-signals based on the N first sub-coefficients and the first input signal, and then generate N first output sub-signals based on the N second sub-signals and the N second sub-coefficients.

It should be noted that N is selected by considering factors such as final output performance and computing resources.

Optionally, in some embodiments, N=1, and the second coefficient is a constant.

Optionally, in some embodiments, N=2.

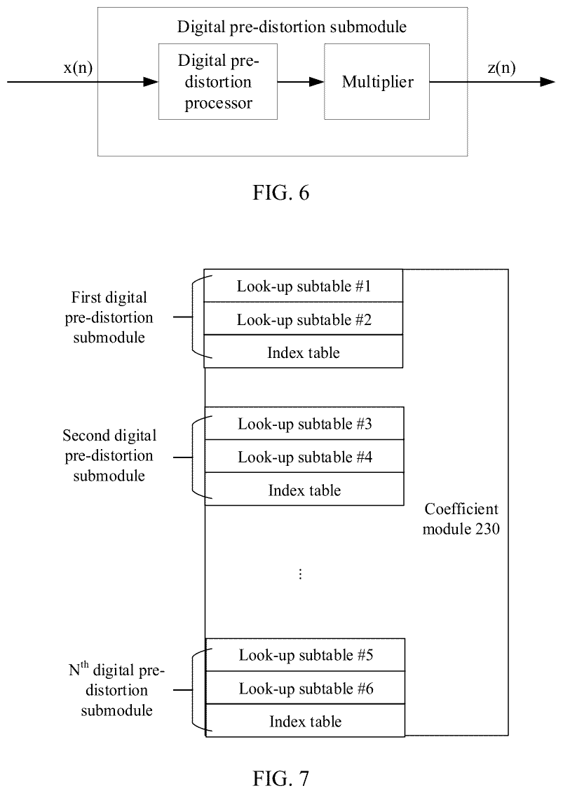

FIG. 6 is a diagram of a structure of the DPD submodule. As shown in FIG. 6, the DPD submodule may include a DPD processor and a multiplier. The first input signal x(n) is input to the DPD submodule. The pre-distortion processor may determine the first sub-coefficient and the second coefficient based on the first input signal, and then the pre-distortion processor may multiply the first input signal by the first sub-coefficient, that is, multiply the first input signal by the DPD coefficient or the plurality of DPD coefficients of different memory terms, to generate a second sub-signal, and then multiply the second sub-signal by the second coefficient through the multiplier, to generate the first output sub-signal. It may be understood that the N first output sub-signals may be obtained through the N DPD submodules, and then the synthesis module may obtain the first output signal according to Formula (2).

$$v ( n ) = {\sum }_{k = 1}^{N} {z}_{k} ( n ) \qquad ( 2 )$$

It should be noted that an architecture of the DPD processor is not limited in embodiments of this disclosure. For example, the architecture of the DPD processor may be an architecture based on the memory polynomial.

The DPD submodule may determine the first sub-coefficient and the second coefficient in the following several manners.

In a possible implementation, each DPD submodule stores an LUT and an index table that correspond to the DPD submodule. The LUT table corresponding to each DPD submodule may include LUTs of different memory terms. The DPD submodule may determine the first sub-coefficient and the second coefficient based on the first feature and the second feature of the first input signal.

It should be understood that, for descriptions that the DPD submodule stores the LUT and the index table that correspond to the DPD submodule, refer to the foregoing descriptions. For brevity, details are not described herein again.

In a possible implementation, the DPD submodule may determine, through the coefficient module 230, the first sub-coefficient and the second coefficient that correspond to the first input signal.

For example, the coefficient module 230 stores the LUT and the index table that correspond to each DPD submodule. The LUT corresponding to each DPD submodule may include sub-LUTs of different memory terms. For example, FIG. 7 is a diagram of a structure in which the coefficient module stores the LUT and the index table. As shown in FIG. 7, each of the N DPD submodules corresponds to one or more sub-LUTs and one or more environment index tables in the coefficient module 230. A quantity of the sub-LUT tables is related to the memory depth. For example, when a memory depth of an MP model is 3, there are three sub-LUTs. When two memory depths of a GMP model are 3 and 5 respectively, there are 15 sub-LUTs. Memory depths and memory terms in different DPD submodules may be the same or may be different. A quantity of the environment index tables is related to the second feature. For example, when the second feature includes M environment sub-features, each of the N DPD submodules includes M environment index tables. When the first input signal is input to the DPD submodule, each DPD submodule may determine the first sub-coefficient and the second sub-coefficient from the corresponding LUT and environment index table, to generate the first output sub-signal.

It should be noted that the first sub-coefficient and the second sub-coefficient that are determined by each of the N DPD submodules based on the first feature and the second feature of the first input signal may be the same or different.

After generating the first output signal, the DPD module 210 may input the first output signal to the PA 220, and the PA 220 may generate the second output signal based on the first output signal.

According to the DPD circuit provided in this embodiment of this disclosure, the DPD module 210 may determine the first coefficient and the second coefficient based on the first feature and the second feature of the first input signal, perform DPD on the first input signal by using the first coefficient and the second coefficient, and then input a first output signal obtained through DPD to the PA 220, to obtain the second output signal that is linear and undistorted.

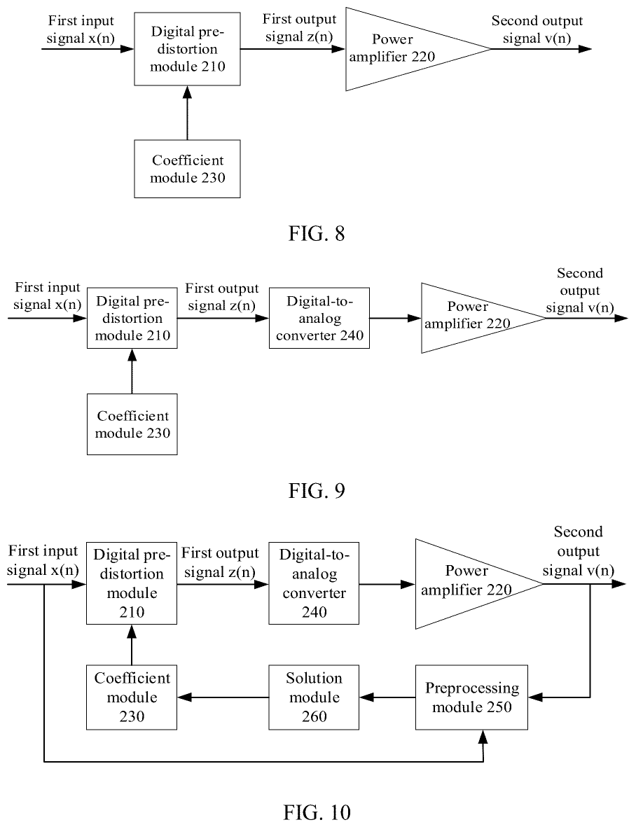

Optionally, in some embodiments, as shown in FIG. 8, the DPD circuit 200 further includes the coefficient module 230. The coefficient module 230 stores the LUT and the index table.

It should be understood that, for descriptions of the coefficient module 230, refer to the foregoing descriptions. For brevity, details are not described herein again.

Optionally, in some embodiments, the PA may be a digital PA, or may be an analog PA. As shown in FIG. 9, the DPD circuit 200 further includes a digital-to-analog converter (DAC) 240. The DAC 240 is configured to: convert the first output signal from the DPD module 210 to obtain an analog signal, and input the analog signal to the PA 220.

Further, in some embodiments, the DPD circuit 200 further includes a passive component such as a filter or a frequency mixer between the DAC and the PA 220.

It should be noted that a type of the passive component is not limited in embodiments of this disclosure.

The coefficient in the LUT and the coefficient in the index table that are stored in the DPD module 210 or the coefficient module 230 may be solved in advance.

For example, the second feature is the bandwidth. When the coefficient in the LUT and the coefficient in the index table are solved, DPD input signals and PA output signals in different bandwidths may be collected, to obtain a DPD coefficient and an index coefficient through solution according to a solution algorithm.

For example, when there are the plurality of second features, for example, the second feature includes the bandwidth and the temperature, when the coefficient in the LUT and the coefficient in the index table are solved, DPD input signals and PA output signals at different bandwidths and temperatures may be collected for solution, to obtain two index tables, which correspond to the two second features: the bandwidth and the temperature respectively.

It may be understood that, in this embodiment of this disclosure, when the input signal and the output signal are solved, the second feature of the input signal is decoupled from the first feature of the input signal, so that the DPD coefficient corresponding to the first feature and the coefficient corresponding to the second feature can be obtained. Further, when a second feature is added or a value range of a specific second feature is changed, an index table corresponding to the second feature may be added or adjusted without changing the LUT of the DPD, so that a quantity of LUTs can be reduced, and storage pressure of a memory can be reduced.

It should be noted that, during solving, the first coefficient and the second coefficient may be determined based on a preset non-linear model according to the solution algorithm. For example, the non-linear model may be the memory polynomial model shown in Formula (1), or may be another model. This is not limited in this disclosure. In addition, a solution method is not limited in this embodiment of this disclosure. For example, a least square (LS) algorithm and a variation thereof, or a least mean square (LMS) algorithm and a variation thereof may be used.

Optionally, in some embodiments, as shown in FIG. 10, the DPD circuit 200 further includes a preprocessing module 250 and a solution module 260. The foregoing coefficient solution method may be preset in the solution module 260.

The first input signal and the second output signal are input to the preprocessing module 250, and an input signal of the preprocessing module 250 is input to the solution module 260.

An ACLR of the first input signal to the second output signal exceeds a first threshold and/or an EVM exceeds a second threshold.

In this case, the preprocessing module 250 is configured to preprocess the first input signal and the second output signal, to align the first input signal with the second output signal.

A preprocessing method used by the preprocessing module 250 is not limited in this embodiment of this disclosure. For example, the preprocessing module 250 may use a preprocessing method such as gain alignment, delay alignment, or frequency/phase offset correction.

The preprocessing module 250 is further configured to input a preprocessed first input signal and second output signal to the solution module 260.

The solution module 260 is configured to process the preprocessed first input signal and second output signal according to an algorithm, to generate a third coefficient and a fourth coefficient.

Optionally, the solution module 260 is further configured to send the third coefficient and the fourth coefficient to the coefficient module 230.

The DPD module 210 is further configured to generate a third signal based on the first input signal and the third coefficient.

The DPD module 210 is further configured to generate a third output signal based on the third signal and the fourth coefficient.

The DPD module 210 is further configured to input the third output signal to the PA 220.

The PA 220 is further configured to amplify the third output signal.

In this embodiment of this disclosure, an amplified third output signal may be referred to as a fourth output signal.

Optionally, in some embodiments, the first coefficient may be replaced with the third coefficient, and the second coefficient may be replaced with the fourth coefficient.

In this embodiment of this disclosure, when the ACLR of the first input signal to the second output signal or the EVM exceeds the threshold, the DPD circuit may re-solve for a new coefficient based on the first input signal and the second output signal, so that the DPD circuit can generate the third output signal based on the third coefficient and the fourth coefficient, and then input the third output signal to the PA, to further obtain the undistorted fourth output signal.

Further, in some embodiments, the DPD circuit may further include a buffer. The buffer is configured to: store the first input signal and the second output signal, and then input the first input signal and the second output signal to the preprocessing module.

In this embodiment of this disclosure, the DPD circuit may further include the preprocessing module and the solution module. When the coefficient in the coefficient module cannot ensure performance of the DPD module, the coefficient in the coefficient module may be updated in real time to adapt to the input signal, to ensure that the PA output signal is not distorted.

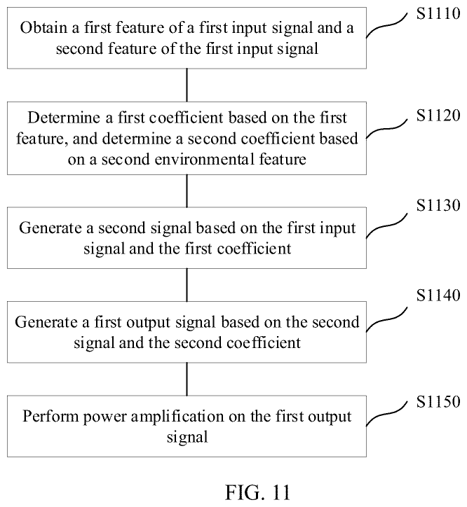

The foregoing describes the DPD circuit provided in embodiments of this disclosure. The following describes a DPD method provided in embodiments of this disclosure. FIG. 11 is a schematic flowchart of a DPD method 1100 according to an embodiment of this disclosure. The method is applied to a transmitting apparatus or a sending apparatus including the transmitting apparatus. The transmitting apparatus includes a DPD processing module, a PA, and a memory. The memory stores an LUT and index table of a DPD. As shown in FIG. 11, the method 1100 includes the following steps.

S1110: Obtain a first feature of a first input signal and a second feature of the first input signal.

The transmitting apparatus may obtain the first input signal. The first input signal may be an LTE signal, a 5G signal, a continuous wave signal, or the like, to obtain the first feature of the first input signal and the second feature of the first input signal.

S1120: Determine a first coefficient based on the first feature of the first input signal, and determine a second coefficient based on the second feature.

The transmitting apparatus may determine the first coefficient based on the first feature of the first input signal, and determine the second coefficient based on the second feature.

S1130: Generate a second signal based on the first input signal and the first coefficient.

The transmitting apparatus may generate the second signal based on the first input signal and the first coefficient.

S1140: Generate a first output signal based on the second signal and the second coefficient.

The transmitting apparatus may generate the first output signal based on the second signal and the second coefficient.

S1150: Perform power amplification on the first output signal, to generate a second output signal.

The transmitting apparatus may process the first output signal by using the PA, to generate the second output signal.

It should be understood that, for descriptions of S1110 to S1150, refer to the foregoing descriptions. For brevity, details are not described herein again.

In this embodiment of this disclosure, the transmitting apparatus may determine the first coefficient and the second coefficient based on the first feature and the second feature of the first input signal, perform DPD on the first input signal by using the first coefficient and the second coefficient, and then input a first output signal obtained through DPD to the PA, to obtain the second output signal that is linear and undistorted.

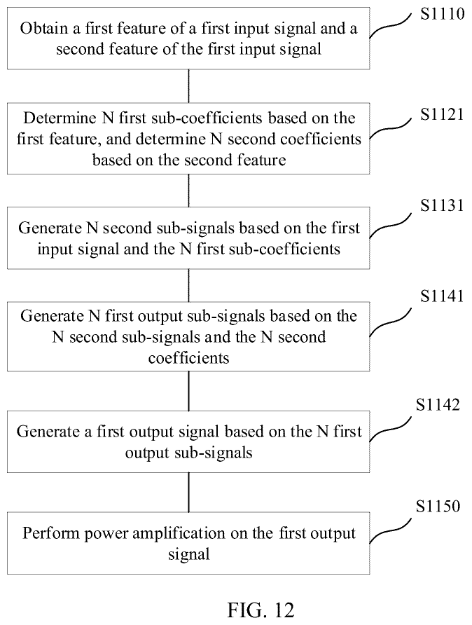

FIG. 12 is a schematic flowchart of an example of a DPD method according to an embodiment of this disclosure. As shown in FIG. 12, in S1120, determining the first coefficient based on the first feature of the first input signal and determining the second coefficient based on the second feature include the following step.

S1121: Determine N first sub-coefficients and N second sub-coefficients based on the first feature and the second feature of the first input signal.

The transmitting apparatus may determine the N first sub-coefficients and the N second sub-coefficients based on the first feature and the second feature of the first input signal.

In S1130, generating the second signal based on the first input signal and the first coefficient includes the following step.

S1131: Generate N second sub-signals based on the first input signal and the N first sub-coefficients.

The transmitting apparatus may generate the N second sub-signals based on the first input signal and the N first sub-coefficients.

In S1140, generating the first output signal based on the second signal and the second coefficient includes the following steps.

S1141: Generate N first output sub-signals based on the N second sub-signals and the N second sub-coefficients.

S1142: Generate the first output signal based on the N first output sub-signals.

The transmitting apparatus may generate the N first output sub-signals based on the N second sub-signals and the N second coefficients, and then sum the N first output sub-signals to obtain the first output signal.

It should be understood that, for detailed descriptions of S1121, S1131, S1141, and S1142, refer to the foregoing descriptions. For brevity, details are not described herein again.

Optionally, in some embodiments, when the second feature of the first input signal includes M second features, the method 1100 further includes: determining M second sub-coefficients based on the M second features of the first input signal.

In S1120, determining the second coefficient of the first input signal based on the second feature includes: determining the second coefficient based on the M second sub-coefficients.

After determining the M second sub-coefficients, the transmitting apparatus may determine the second coefficient based on the M sub-coefficients.

For example, the M second sub-coefficients may be multiplied to obtain the second coefficient.

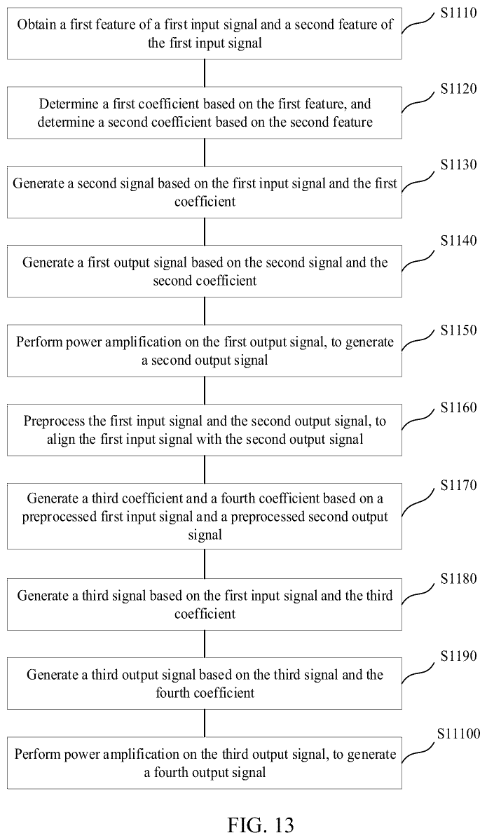

FIG. 13 is a schematic flowchart of an example of a DPD method according to an embodiment of this disclosure. As shown in FIG. 13, when an ACLR of the first input signal to the second output signal exceeds a first threshold and/or an EVM exceeds a second threshold, the method 1100 further includes the following steps.

S1160: Preprocess the first input signal and the second output signal, to align the first input signal with the second output signal.

S1170: Process a preprocessed first input signal and a preprocessed second output signal, to generate a third coefficient and a fourth coefficient.

S1180: Generate a third signal based on the first input signal and the third coefficient.

S1190: Generate a third output signal based on the third signal and the fourth coefficient.

S11100: Process the third output signal by using the PA, to generate a fourth output signal. In this embodiment of this disclosure, when the ACLR of the first input signal to the second output signal exceeds the first threshold and/or the EVM exceeds the second threshold, the DPD circuit may re-solve for a new coefficient based on the first input signal and the second output signal, so that the DPD circuit can generate the third output signal based on the third coefficient and the fourth coefficient, and then input the third output signal to the PA, to further obtain the undistorted fourth output signal.

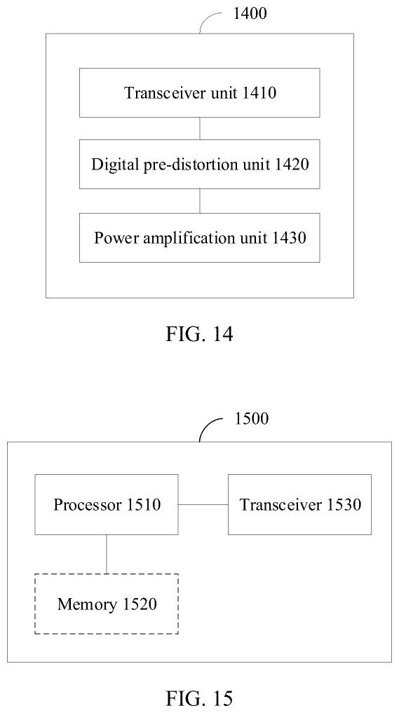

FIG. 14 shows a transmitting apparatus 1400 according to an embodiment of this disclosure. The transmitting apparatus 1400 is used in a sending device. As shown in FIG. 14, the transmitting apparatus 1400 includes a transceiver unit 1410, a DPD unit 1420, and a power amplification unit 1430.

The transceiver unit 1410 is configured to receive a first input signal.

The DPD unit 1420 is configured to obtain a first feature of a first input signal and a second feature of the first input signal.

The DPD unit 1420 is configured to: determine a first coefficient based on the first feature, and determine a second coefficient based on the second feature.

The DPD unit 1420 is further configured to generate a second signal based on the first input signal and the first coefficient.

The DPD unit 1420 is further configured to generate a first output signal based on the second signal and the second coefficient.

The DPD unit 1420 is further configured to input the first output signal to the power amplification unit 1430.

The power amplification unit 1430 is configured to generate a second output signal based on the first output signal.

The transceiver unit 1410 is further configured to send the second output signal.

Optionally, in some embodiments, the transmitting apparatus further includes a coefficient unit. The coefficient unit stores an LUT and an index table.

The DPD unit 1420 is configured to: extract the first coefficient from the coefficient unit based on the first feature, and extract the second coefficient from the coefficient unit based on the second feature.

Optionally, in some embodiments, the DPD unit 1420 is configured to: determine N first sub-coefficients based on the first feature of the first input signal, and determine N second sub-coefficients based on the second feature; generate N second sub-signals based on the first input signal and N first coefficients; generate N first output sub-signals based on the N second sub-signals and the N second sub-coefficients; and generate the first output signal based on the N first output sub-signals.

Optionally, in some embodiments, the second feature includes M second sub-features, and the DPD unit 1420 is configured to: determine M second sub-coefficients based on the M second sub-features of the first input signal, where M≥1 and is an integer; and determine the second coefficient based on the M second sub-coefficients.

Optionally, in some embodiments, the transmitting apparatus 1400 further includes a preprocessing unit and a solution unit. An algorithm used to solve for a coefficient may be preset in the solution unit. The first input signal and the second output signal are input to the preprocessing unit. When an ACLR of the first input signal to the second output signal exceeds a first threshold or an EVM exceeds a second threshold, the preprocessing unit is configured to preprocess the first input signal and the second output signal, to align the first input signal with the second output signal.

The preprocessing unit is further configured to input a preprocessed first input signal and a preprocessed second output signal to the solution unit.

The solution unit is configured to process the preprocessed first input signal and the preprocessed second output signal according to the algorithm, to generate a third coefficient and a fourth coefficient.

Optionally, the solution unit is further configured to input the third coefficient and the fourth coefficient to the coefficient unit.

The DPD unit 1420 is further configured to generate a third signal based on the first input signal and the third coefficient.

The DPD unit 1420 is further configured to generate a third output signal based on the third signal and the fourth coefficient.

The DPD unit 1420 is further configured to input the third output signal to the power amplification unit 1430.

The power amplification unit 1430 is further configured to generate a fourth output signal based on the third output signal.

The transceiver unit 1410 is further configured to send the fourth output signal.

As shown in FIG. 15, an embodiment of this disclosure further provides a communication apparatus (for example, a transmitting device) 1500. The communication apparatus 1500 includes a processor 1510. The processor 1510 is coupled to a memory 1520. The memory 1520 is configured to store a computer program or instructions and/or data. The processor 1510 is configured to execute the computer program or the instructions and/or the data stored in the memory 1520, so that the method in the foregoing method embodiments is performed.

Optionally, the communication apparatus 1500 includes one or more processors 1510.

Optionally, the communication apparatus 1500 may include one or more memories 1520.

Optionally, the memory 1520 and the processor 1510 may be integrated together or disposed separately.

Optionally, as shown in FIG. 15, the wireless communication apparatus 1500 may further include a transceiver 1530. The transceiver 1530 is configured to: receive and/or send a signal. For example, the processor 1510 is configured to control the transceiver 1530 to receive and/or send the signal.

In a solution, the communication apparatus 1500 is configured to implement operations performed by the units in the transmitting apparatus in the foregoing method embodiments.

An embodiment of this disclosure further provides a computer-readable storage medium. The computer-readable storage medium stores computer instructions used to implement the method performed by the transmitting apparatus or the method performed by the transmitting apparatus in the foregoing method embodiments.

An embodiment of this disclosure further provides a computer program product. When a computer program is executed by a computer, the computer is enabled to implement the method performed by the transmitting device in the foregoing method embodiments.

An embodiment of this disclosure further provides a communication system. The communication system includes the communication device in the foregoing embodiments.

For explanations and beneficial effects of related content of any wireless communication apparatus provided above, refer to the corresponding method embodiment provided above. Details are not described herein again.

In this embodiment of this disclosure, the communication device may include a hardware layer, an operating system layer running above the hardware layer, and an application layer running above the operating system layer. The hardware layer may include hardware such as a central processing unit (CPU), a memory management unit (MMU), and memory (also referred to as main memory). An operating system at the operating system layer may be any one or more computer operating systems that implement service processing through a process, for example, a LINUX operating system, a UNIX operating system, an ANDROID operating system, an iOS operating system, or a WINDOWS operating system. The application layer may include applications such as a browser, an address book, word processing software, and instant messaging software.

A specific structure of an execution body of the method provided in embodiments of this disclosure is not limited in embodiments of this disclosure, provided that a program that records code of the method provided in embodiments of this disclosure can be run to perform communication according to the method provided in embodiments of this disclosure. For example, the execution body of the method provided in embodiments of this disclosure may be a terminal device or a satellite, or may be a functional module that is in the terminal device or the satellite and that can invoke a program and execute the program.

Aspects or features in embodiments of this disclosure may be implemented as a method, an apparatus, or a product that uses standard programming and/or engineering technologies. The term “product” used in this specification may cover a computer program that can be accessed from any computer-readable component, carrier or medium. For example, a computer-readable medium may include but is not limited to a magnetic storage component (for example, a hard disk, a floppy disk, or a magnetic tape), an optical disc (for example, a compact disc (CD) or a digital versatile disc (DVD)), a smart card, and a flash memory component (for example, an erasable programmable read-only memory (EPROM), a card, a stick, or a key drive).

Various storage media described in this specification may indicate one or more devices and/or other machine-readable media that are configured to store information. The term “machine-readable media” may include but is not limited to a radio channel and various other media that can store, include, and/or carry instructions and/or data.

It should be understood that the processor in embodiments of this disclosure may be a CPU, another general-purpose processor, a digital signal processor (DSP), an application-specific integrated circuit (ASIC), a field-programmable gate array (FPGA) or another programmable logic device, a discrete gate or transistor logic device, a discrete hardware component, or the like. The general-purpose processor may be a microprocessor, or the processor may be any other processor or the like.

It should be further understood that the memory mentioned in embodiments of this disclosure may be a volatile memory or a non-volatile memory, or may include a volatile memory and a non-volatile memory. The non-volatile memory may be a read-only memory (ROM), a programmable read-only memory (PROM), an erasable programmable read-only memory (EPROM), an electrically erasable programmable read-only memory (EEPROM), or a flash memory. The volatile memory may be a random-access memory (RAM). For example, the RAM may be used as an external cache. By way of example and not limitation, the RAM may include the following plurality of forms: a static random-access memory (SRAM), a dynamic random-access memory (DRAM), a synchronous dynamic random-access memory (SDRAM), a double data rate synchronous dynamic random-access memory (DDR SDRAM), an enhanced synchronous dynamic random-access memory (ESDRAM), a synchlink dynamic random-access memory (SLDRAM), and a direct Rambus random-access memory (DR RAM).

It should be noted that, when the processor is a general-purpose processor, a DSP, an ASIC, an FPGA or another programmable logic device, a discrete gate or a transistor logic device, or a discrete hardware component, the memory (storage module) may be integrated into the processor.

It should further be noted that the memory described herein is intended to include but is not limited to these and any other appropriate type of memory.

A person of ordinary skill in the art may be aware that, in combination with the examples described in embodiments disclosed in this specification, units and algorithm steps may be implemented by electronic hardware or a combination of computer software and electronic hardware. Whether the functions are performed by hardware or software depends on particular applications and design constraint conditions of the technical solutions. A person skilled in the art may use different methods to implement the described functions for each particular application, but it should not be considered that the implementation goes beyond the scope of embodiments of this disclosure.

It may be clearly understood by a person skilled in the art that, for the purpose of convenient and brief description, for a detailed working process of the foregoing system, apparatus, and unit, refer to a corresponding process in the foregoing method embodiments. Details are not described herein again.

In the several embodiments provided in embodiments of this disclosure, it should be understood that the disclosed system, apparatus, and method may be implemented in other manners. For example, the described apparatus embodiment is merely an example. For example, the described apparatus embodiments are merely examples. For example, division into the units is merely logical function division and may be other division in actual implementation. For example, a plurality of units or components may be combined or integrated into another system, or some features may be ignored or may not be performed. In addition, the displayed or discussed mutual couplings or direct couplings or communication connections may be implemented through some interfaces. The indirect couplings or communication connections between the apparatuses or units may be implemented in electronic, mechanical, or other forms.

The units described as separate parts may or may not be physically separate, and parts displayed as units may or may not be physical units, may be located in one position, or may be distributed on a plurality of network units. Some or all of the units may be selected according to actual requirements to achieve the objectives of the solutions of embodiments.

In addition, functional units in embodiments of this disclosure may be integrated into one processing unit, each of the units may exist alone physically, or two or more units may be integrated into one unit.

When the functions are implemented in a form of software functional unit and sold or used as an independent product, the functions may be stored in a computer-readable storage medium. Based on such an understanding, the technical solutions of embodiments of this disclosure essentially, or the part contributing to another technology, or some of the technical solutions may be implemented in a form of software product. The computer software product is stored in a storage medium, and includes several instructions for instructing a computer device (which may be a personal computer, a server, a network device, or the like) to perform all or some of the steps of the methods described in embodiments of this disclosure. The foregoing storage medium includes any medium that can store program code, such as a Universal Serial Bus (USB) flash drive, a removable hard disk, a read-only memory (ROM), a random-access memory (RAM), a magnetic disk, or an optical disc.

The foregoing descriptions are merely specific implementations of this disclosure, but are not intended to limit the protection scope of this disclosure. Any variation or replacement readily figured out by a person skilled in the art within the technical scope disclosed in embodiments of this disclosure shall fall within the protection scope of this disclosure. Therefore, the protection scope of this disclosure shall be subject to the protection scope of the claims.

What is claimed is:

1. A digital pre-distortion (DPD) circuit, comprising:
a DPD sub-circuit configured to:
obtain a first feature of a first input signal, wherein the first feature comprises at least one of an amplitude of the first input signal, an in-phase component of the first input signal, or a quadrature component of the first input signal;
obtain a second feature of the first input signal, wherein the second feature comprises at least one of a bandwidth of the first input signal, a temperature at which the DPD circuit processes the first input signal, a frequency of the first input signal, a modulation format of the first input signal, or a standing wave generated when the DPD circuit processes the first input signal;
determine, based on the first feature, a first coefficient;
determine, based on the second feature, a second coefficient;
generate, based on the first input signal and the first coefficient, a second signal;
generate, based on the second signal and the second coefficient, a first output signal; and
output the first output signal; and
a power amplifier (PA) configured to:
receive, from the DPD sub-circuit, the first output signal; and
amplify the first output signal to generate a second output signal.

2. The DPD circuit of claim 1, further comprising a coefficient sub-circuit configured to store a first correspondence between the first feature and the first coefficient and a second correspondence between the second feature and the second coefficient, and wherein the DPD sub-circuit is further configured to:
extract, based on the first feature and from the coefficient sub-circuit, the first coefficient; and
extract, based on the second feature and from the coefficient sub-circuit, the second coefficient.

3. The DPD circuit of claim 1, wherein the DPD sub-circuit comprises:
N DPD sub-circuits configured to:
determine, based on the first feature, N first sub-coefficients, wherein N is an integer, and wherein N≥1;
determine, based on the second feature, N second sub-coefficients;
generate, based on the first input signal and the N first sub-coefficients, N second sub-signals; and
generate, based on the N second sub-signals and the N second sub-coefficients, N first output sub-signals; and
a synthesis sub-circuit configured to generate, based on the N first output sub-signals, the first output signal.

4. The DPD circuit of claim 1, further comprising:
a preprocessing sub-circuit configured to:
receive the first input signal and the second output signal; and
when an adjacent channel leakage ratio (ACLR) of the first input signal to the second output signal exceeds a first threshold or an error vector magnitude exceeds a second threshold:
preprocess the first input signal and the second output signal to align the first input signal with the second output signal and obtain a preprocessed first input signal and a preprocessed second output signal; and
output the preprocessed first input signal and the preprocessed second output signal; and
a solution sub-circuit configured to:
store an algorithm for solving for a coefficient;
receive, from the preprocessing sub-circuit, the preprocessed first input signal and the preprocessed second output signal; and
process, according to the algorithm, the preprocessed first input signal and the preprocessed second output signal to generate a third coefficient and a fourth coefficient, and
wherein the DPD sub-circuit is further configured to:
generate, based on the first input signal and the third coefficient, a third signal;
generate, based on the third signal and the fourth coefficient, a third output signal; and
input the third output signal to the PA, and
wherein the PA is configured to amplify the third output signal.

5. The DPD circuit of claim 1, further comprising a digital-to-analog converter (DAC) configured to:
obtain, from the DPD circuit, the first output signal;
perform digital-to-analog conversion on the first output signal to obtain an analog output signal; and
input, to the PA, the analog output signal.

6. A method, comprising:
obtaining a first feature of a first input signal, wherein the first feature comprises at least one of an amplitude of the first input signal, an in-phase component of the first input signal, or a quadrature component of the first input signal;
obtaining a second feature of the first input signal, wherein the second feature comprises at least one of a bandwidth of the first input signal, a temperature at which a digital pre-distortion (DPD) circuit processes the first input signal, a frequency of the first input signal, a modulation format of the first input signal, or a standing wave generated when the DPD circuit processes the first input signal;
determining, based on the first feature, a first coefficient;
determining, based on the second feature, a second coefficient;
generating, based on the first input signal and the first coefficient, a second signal;
generating, based on the second signal and the second coefficient, a first output signal; and
performing power amplification on the first output signal to generate a second output signal.

7. The method of claim 6, wherein determining the first coefficient and the second coefficient comprises:
determining, based on the first feature, N first sub-coefficients; and
determining, based on the second feature, N second sub-coefficients,
wherein generating the second signal comprises generating, based on the first input signal and the N first sub-coefficients, N second sub-signals, and
wherein generating the first output signal comprises:
generating, based on the N second sub-signals and the N second sub-coefficients, N first output sub-signals; and
generating, based on the N first output sub-signals, the first output signal.

8. The method of claim 6, wherein when an adjacent channel leakage ratio (ACLR) of the first input signal to the second output signal exceeds a first threshold or an error vector magnitude exceeds a second threshold, the method further comprises:
preprocessing the first input signal and the second output signal to align the first input signal with the second output signal and obtain a preprocessed first input signal and a preprocessed second output signal;
processing the preprocessed first input signal and the preprocessed second output signal to generate a third coefficient and a fourth coefficient;
generating, based on the first input signal and the third coefficient, a third signal;
generating, based on the third signal and the fourth coefficient, a third output signal; and
performing power amplification on the third output signal to generate a fourth output signal.

9. A transmitting apparatus, comprising:
a transceiver configured to receive a first input signal;
a digital pre-distortion (DPD) circuit configured to:
obtain a first feature of the first input signal, wherein the first feature comprises at least one of: an amplitude of the first input signal, an in-phase component of the first input signal, or a quadrature component of the first input signal;
obtain a second feature of the first input signal, wherein the second feature comprises at least one of: a bandwidth of the first input signal, a temperature at which the DPD circuit processes the first input signal, a frequency of the first input signal, a modulation format of the first input signal, or a standing wave generated when the DPD circuit processes the first input signal;
determine, based on the first feature, a first coefficient;
determine, based on the second feature, a second coefficient;
generate, based on the first input signal and the first coefficient, a second signal;
generate, based on the second signal and the second coefficient, a first output signal; and
output the first output signal; and
a power amplifier (PA) configured to:
receive, from the DPD circuit, the first output signal;
amplify the first output signal to generate a second output signal; and
output the second output signal to the transceiver.

10. The transmitting apparatus of claim 9, further comprising a coefficient sub-circuit configured to store a first correspondence between the first feature and the first coefficient and a second correspondence between the second feature and the second coefficient, and wherein the DPD circuit is further configured to:
extract, based on the first feature and from the coefficient sub-circuit, the first coefficient; and
extract, based on the second feature and from the coefficient sub-circuit, the second coefficient.

11. The transmitting apparatus of claim 9, wherein the DPD circuit is further configured to:
determine, based on the first feature, N first sub-coefficients;
determine, based on the second feature, N second sub-coefficients;
generate, based on the first input signal and the N first coefficients, N second sub-signals;
generate, based on the N second sub-signals and the N second sub-coefficients, N first output sub-signals; and
generate, based on the N first output sub-signals, the first output signal.

12. The transmitting apparatus of claim 9, further comprising:
a preprocessing sub-circuit configured to:
receive the first input signal and the second output signal; and
when an adjacent channel leakage ratio (ACLR) of the first input signal to the second output signal exceeds a first threshold or an error vector magnitude exceeds a second threshold:
preprocess the first input signal and the second output signal to align the first input signal with the second output signal and obtain a preprocessed first input signal and a preprocessed second output signal; and
output the preprocessed first input signal and the preprocessed second output signal; and
a solution sub-circuit configured to:
store an algorithm used to solve for a coefficient;
receive, from the preprocessing sub-circuit, the preprocessed first input signal and the preprocessed second output signal; and
process, according to the algorithm, the preprocessed first input signal and the preprocessed second output signal to generate a third coefficient and a fourth coefficient,
wherein the DPD circuit is further configured to:
generate, based on the first input signal and the third coefficient, a third signal;
generate, based on the third signal and the fourth coefficient, a third output signal; and
input the third output signal to the PA,
wherein the PA is further configured to amplify the third output signal to generate an amplified third output signal, and
wherein the transceiver is further configured to send the amplified third output signal.

13. The transmitting apparatus of claim 9, wherein the first input signal comprises a modulation signal.

14. The transmitting apparatus of claim 9, wherein the first input signal comprises a Long-Term Evolution (LTE) signal.

15. The transmitting apparatus of claim 9, wherein the first input signal comprises a fifth generation (5G) signal.

16. The transmitting apparatus of claim 9, wherein the first input signal comprises a continuous wave (CW) signal.

17. The transmitting apparatus of claim 9, wherein the DPD is configured to generate the first output signal using a Volterra model.

18. The transmitting apparatus of claim 9, wherein the DPD is configured to generate the first output signal using a Hammerstein model.

19. The transmitting apparatus of claim 9, wherein the DPD is configured to generate the first output signal using a Weiner model.

20. The transmitting apparatus of claim 9, wherein the DPD is configured to generate the first output signal using a polynomial model.
